(19) United States
(12) Patent Application Publication
(10) Pub. No.: US 2018/0040802 A1
(43) Pub. Date: Feb. 8, 2018

(54) ELECTRONIC DEVICE AND MANUFACTURING METHOD OF ELECTRONIC DEVICE

(71) Applicant: Yoshikazu AKIYAMA, Kanagawa (JP)

(72) Inventor: Yoshikazu AKIYAMA, Kanagawa (JP)

(21) Appl. No.: 15/727,331

(22) Filed: Oct. 6, 2017

Related U.S. Application Data
(62) Division of application No. 14/542,781, filed on Nov. 17, 2014.

(30) Foreign Application Priority Data
Nov. 27, 2013 (JP) 2013-245292

(51) Int. Cl. H01L 41/08; H01L 27/20; H01L 41/331; H01L 41/318; H01L 41/047

(52) U.S. Cl. CPC H01L 41/0805; H01L 41/331; H01L 41/318; H01L 27/20; H01L 41/0825; H01L 41/0478

(57) ABSTRACT

An electronic device includes a substrate; a first thin-film element formed on the substrate and having a lower electrode, a first upper electrode and a first thin-film part disposed between the lower electrode and the first upper electrode; and a second thin-film element formed on the substrate and having the lower electrode, a second upper electrode and a second thin-film part disposed between the lower electrode and the second upper electrode. Film thicknesses of the first and second thin-film parts are different from each other. The first thin-film part is formed by applying a precursor solution using a printing method to form a first precursor thin-film and imparting energy to the first precursor thin-film, and the second thin-film part is formed by applying the precursor solution using the printing method to form a second precursor thin-film and imparting energy to the second precursor thin-film.

### CROSS REFERENCE TO RELATED APPLICATION

The present application is a division of U.S. patent application Ser. No. 14/542,781, filed Nov. 17, 2017, which claims priority to Japanese Patent Application No. 2013-245292 filed in the JPO on Nov. 27, 2013. The contents of the above applications are incorporated herein by reference.

### BACKGROUND OF THE INVENTION

### 1. Field of the Invention

The disclosures herein generally relate to an electronic device and a manufacturing method of an electronic device.

### 2. Description of the Related Art

Conventionally, electronic devices in each of which a thin-film element is formed on a substrate have been known.

Japanese Published Patent Application No. 2000-22233, for example, discloses a piezoelectric body thin-film element including a piezoelectric body film sandwiched between a lower electrode and an upper electrode formed on a substrate via an insulation film.

As disclosed in Japanese Published Patent Application No. 2000-22233, conventionally there have been only electronic devices in each of which a thin-film element provided with a single function or characteristic is formed on a substrate.

Recently, an electronic device provided with plural thin-film elements, functions or characteristics of which are different from each other, is required in order to downsize an apparatus or to reduce cost. The thin-film element is required to include a thin-film part having an optimum film thickness according to the required function or characteristic. Accordingly, the electronic device provided on the substrate with the plural thin-film elements, functions or characteristics of which are different from each other, is required to have plural thin-film elements provided with thin-film parts, film thicknesses of which are different from each other, as described above.

Conventional manufacturing methods for manufacturing electronic devices provided on a substrate with plural thin-film elements, film thicknesses of which are different from each other, include the following method, for example.

At first, as shown in FIG. 1A, a thin film 12 is formed on an entire surface of a substrate 11 by using a spin coating method or the like. Then, as shown in FIG. 1B, one thin-film element 13 is formed by performing an etching processing on the thin film 12. Afterwards, as shown in FIG. 1C, a thin film 14, a film thickness of which is different from that of the thin film 12, is formed on the substrate 11 by using a material of the other thin-film element. Then, as shown in FIG. 1D, by performing the etching processing on the thin film 14, another thin-film element 15 is formed. In some cases, by repeating the above processes plural times, plural thin-film elements are formed.

According to the above method, since the thin-film element 13 has already been formed on the substrate when the thin film 14 is formed, the thin film 14 is formed in a state where the surface of the substrate 11 includes concavities and convexities. However, when the surface of the substrate has a concavo-convex shape, a uniform thin film cannot be formed, and the thin-film element 15 having a desired performance cannot be formed. Moreover, since the etching selectivity in the etching process is not high enough, it has been difficult to form the respective thin-film elements having desired shapes.

Due to the reasons described as above, the electronic device provided on a substrate with plural thin-film elements having thin film parts, film thicknesses of which are different from each other, has not been obtained.

### SUMMARY OF THE INVENTION

It is a general object of at least one embodiment of the present invention to provide an electronic device and a manufacturing method of the electronic device that substantially obviate one or more problems caused by the limitations and disadvantages of the related art.

In one embodiment, an electronic device includes a substrate; a first thin-film element formed on the substrate and having a lower electrode, a first upper electrode and a first thin-film part disposed between the lower electrode and the first upper electrode; and a second thin-film element formed on the substrate and having the lower electrode, a second upper electrode and a second thin-film part disposed between the lower electrode and the second upper electrode, wherein a film thickness of the second thin-film part is different from a film thickness of the first thin-film part. The first thin-film part is formed by applying a precursor solution using a printing method to form a first precursor thin-film and imparting energy to the first precursor thin-film, and the second thin-film part is formed by applying the precursor solution using the printing method to form a second precursor thin-film and imparting energy to the second precursor thin-film.

In another embodiment, a manufacturing method is a method of manufacturing an electronic device which includes a substrate, a first thin-film element formed on the substrate and having a lower electrode, a first upper electrode and a first thin-film part disposed between the lower electrode and the first upper electrode, and a second thin-film element formed on the substrate and having the lower electrode, a second upper electrode and a second thin-film part disposed between the lower electrode and the second upper electrode, wherein a film thickness of the second thin-film part is different from a film thickness of the first thin-film part. The method includes performing processing of forming a first precursor thin-film by applying a precursor solution using a printing method; performing processing of forming a second precursor thin-film by applying the precursor solution using the printing method; imparting energy to the first precursor thin-film to form the first thin-film part; and imparting energy to the second precursor thin-film to form the second thin-film part.

According to the present invention, an electronic device provided with plural thin-film elements having thin film parts, film thicknesses of which are different from each other, can be provided.

### BRIEF DESCRIPTION OF THE DRAWINGS

Other objects and further features of embodiments will be apparent from the following detailed description when read in conjunction with the accompanying drawings, in which:

FIGS. 1A to 1D are explanatory diagrams illustrating a manufacturing method of an electronic device provided with plural thin-film elements according to the related art;

FIG. 2 is an explanatory diagram illustrating an example of a configuration of an electronic device according to a present embodiment;

FIGS. 3A and 3B are explanatory diagrams illustrating examples of application density of a precursor solution according to the present embodiment;

FIGS. 4A to 4E are explanatory diagrams illustrating examples of a method of forming thinning data used for thinning a provision of liquid drops of the precursor solution according to the present embodiment;

FIGS. 5A to 5D are explanatory diagrams illustrating an example of a configuration of processes of reforming a surface of a substrate according to the present embodiment;

FIGS. 6A and 6B are explanatory diagrams illustrating examples of a configuration of processes of forming plural thin-film elements according to the present embodiment;

FIGS. 7A to 7C are explanatory diagrams illustrating another example of the configuration of processes of reforming the surface of the substrate according to the present embodiment;

FIGS. 8A to 8C are explanatory diagrams illustrating another example of the configuration of processes of reforming the surface of the substrate according to the present embodiment;

FIGS. 9A to 9C are explanatory diagrams illustrating another example of the configuration of processes of reforming the surface of the substrate according to the present embodiment;

FIGS. 10A and 10B are explanatory diagrams illustrating another example of the configuration of processes of reforming the surface of the substrate according to the present embodiment;

FIG. 11 is a flowchart illustrating an example of a procedure of manufacturing a thin film part according to a present example; and

FIGS. 12A and 12B are diagrams illustrating examples of a bitmap corresponding to the provision pattern for the liquid drop of the precursor solution according to the fourth example.

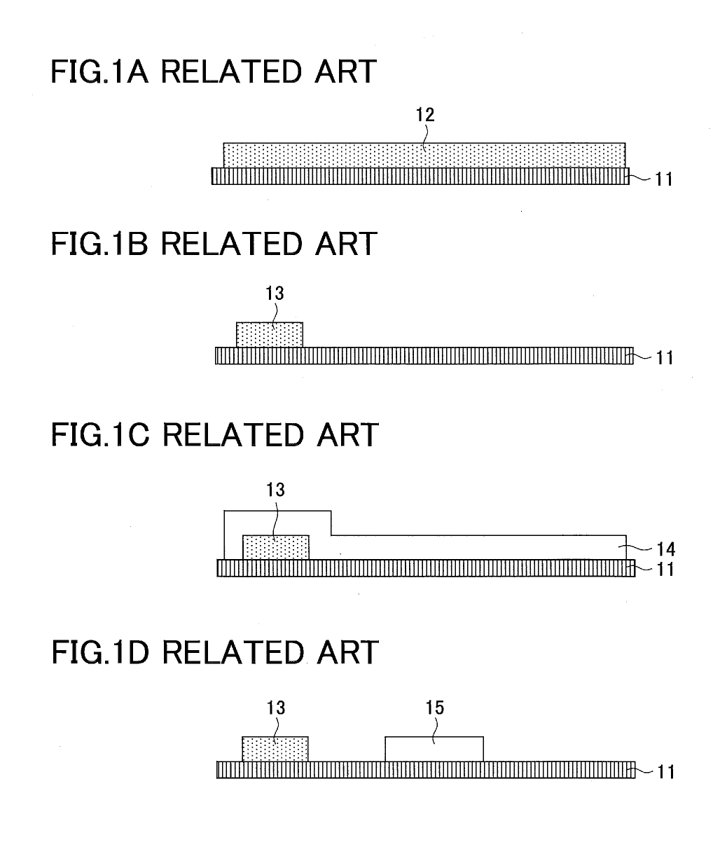

### DESCRIPTION OF THE PREFERRED EMBODIMENTS

In the following, embodiments of the present invention will be described with reference to the accompanying drawings. Meanwhile, the present invention is not limited to these examples.

An example of a configuration of an electronic device according to the present embodiment will be explained.

The electronic device according to the present embodiment includes a substrate, a first thin-film element having a first thin-film part formed on the substrate, and a second thin-film element having a second thin-film part formed on the substrate. Furthermore, a film thickness of the first thin-film part and a film thickness of the second thin-film part are preferably different.

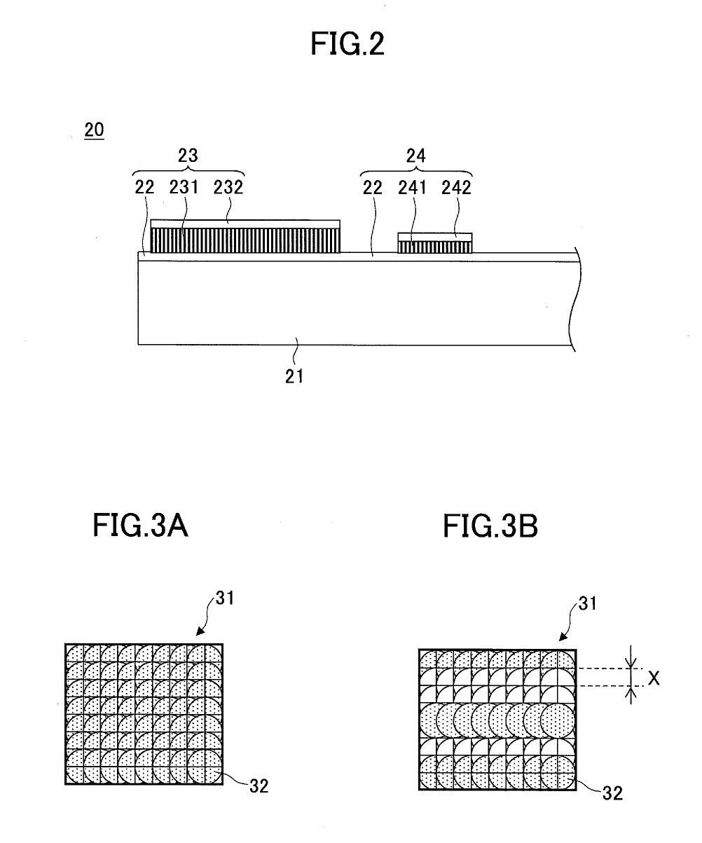

A schematic example of configuration will be explained with reference to FIG. 2. FIG. 2 illustrates a cross-sectional diagram of the electronic device 20 in which two thin-film elements are formed on the substrate 21. In FIG. 2, on the substrate 21 the first thin-film element 23 and the second thin-film element 24 are formed. Meanwhile, in the electronic device according to the present embodiment, a number of the thin-film elements are not particularly limited, and three or more thin-film elements may be formed.

In the following, members included in the electronic device according to the present embodiment and specific configurations will be explained.

Here, at first, a configuration of the substrate 21 is not particularly limited, but the substrate 21 only has to be a substrate that can support plural thin-film elements. A material and a shape of the substrate are not particularly limited. But, for example, a substrate made of silicon, sapphire, single-crystal magnesium oxide or the like can be preferably used. Especially, for the substrate 21, silicon can be preferably used because of its low cost and high workability.

Configurations of the first thin-film element 23 and the second thin-film element 24 are not particularly limited. However, for example, as shown in FIG. 2, electrodes may be arranged on an upper surface and on a lower surface of each of the first thin-film part 231 and the second thin-film part 241 so as to develop the function of each thin-film element. In the first thin-film element 23 and the second thin-film element 24, shown in FIG. 2, upper electrodes 232, 242 as individual electrodes, respectively, and a lower electrode 22 as a common electrode are provided. Meanwhile, both the upper electrode and the lower electrode may be individual electrodes formed on each thin-film element.

A material of the upper electrode and the lower electrode included in the thin-film element is not particularly limited, and may include various electric conducting materials. For example, it is preferable to include a metal such as platinum, rhodium, iridium, ruthenium, palladium, silver or nickel, an alloy of these metals or a conductive oxide material such as ITO (In₂O₃—SnO₂).

Meanwhile, the material of the upper electrode and the material of the lower electrode are not necessarily the same, and the upper and lower electrodes may include different materials. Moreover, each of the upper electrode and the lower electrode may be configured to have plural layers.

Meanwhile, between the substrate and the lower electrode, for example, an adhesion layer or the like may be provided in order to enhance an adhesiveness of the substrate and the lower electrode.

The thin-film element may have a thin-film part provided with any function selected from a positive piezoelectric effect, an inverse piezoelectric effect, an electric charge accumulation, semiconductivity and conductivity. Especially, the thin-film element preferably has a thin-film part provided with any function selected from the positive piezoelectric effect, the inverse piezoelectric effect and the electric charge accumulation. The thin-film element has a function according to the function of the thin-film part.

Here, the thin-film part having the function of the positive piezoelectric effect is a thin-film part having a function of converting a change in pressure into an electric signal. The thin-film element provided with the thin-film part having the function of the positive piezoelectric effect includes, for example, a sensor that outputs an electric signal indicating a change in pressure due to a position variation or the like, a vibration sensor that outputs an electric signal indicating a disturbance such as a vibration, or the like.

Moreover, the thin-film part having the function of the inverse piezoelectric effect is a thin-film part having a function of deforming when a voltage is applied. The thin-film element provided with the thin-film part having a function of a negative piezoelectric effect includes, for example, an actuator or the like.

The thin-film part having the function of the electric charge accumulation is a thin-film part that can accumulate a predetermined amount of electric charges when a voltage is applied. The thin-film element provided with the thin-film part having the electric charge accumulation function includes, for example, a capacitor.

The thin-film element provided with the thin-film part having the function of semiconductivity includes, for example, a semiconductor layer in an element of such as an FET (field-effect transistor), a diode or the like.

The thin-film part having the function of the conductivity is a thin-film part in which an electric current flows when the voltage is applied. The thin-film element provided with the thin-film part having the function of the conductivity includes, for example, a wiring, a thin-film resistor element or the like.

In the electronic device, thin-film elements provided with thin-film parts each having a function arbitrarily selected from the above-described functions may be combined. For example, in the electronic device 20, shown in FIG. 2, the first thin-film element 23 may be the actuator and the second thin-film element 24 may be the sensor or the element having the function of accumulating electric charges. In the case where the first thin-film element 23 is the actuator and the second thin-film element 24 is the sensor, the first thin-film part 231 of the first thin-film element 23 may have the function of the inverse piezoelectric effect, and the second thin-film part 241 of the second thin-film element 24 may have the function of the positive piezoelectric effect.

In the actuator, an amount of displacement for a predetermined voltage may change due to a temporal change or the like. In the electronic device 20 shown in FIG. 2, having the configuration as above, the amount of displacement of the actuator which is the first thin-film element 23 can be detected by the sensor which is the second thin-film element 24.

Here, for a material included in the thin-film part, a desirable material that delivers the above-described performance may be arbitrarily selected and used. Especially, from a viewpoint of ease of treatment upon manufacturing, the thin-film part is preferably made of a metallic oxide film, a so-called ceramics material.

A metallic oxide included in the metallic oxide film is not particularly limited, and a material may be selected according to the function required for the thin-film part. For example, a conductive oxide, an oxide semiconductor, an oxide insulator, a piezoelectric body, a dielectric body or the like may be used.

For example, the conductive oxide includes ITO (In₂O₃—SnO₂), ZnO, Al-doped ZnO, SnO₂, In₂O₃, (La,Sr)CoO₃, LaMnO₃, LaNiO₃, SrRuO₃, or the like. The oxide semiconductor includes IGZO (trademark registered), InMgO₄, ZnO, Nb-doped SrTiO₃, (Ba,Sr)TiO₃ or the like. The oxide insulator includes HfO₂, ZrO₂, Ta₂O₅, SrTiO₃, (Ba,Sr)TiO₃ or the like.

Moreover, the piezoelectric body includes PZT (PbTiO₃—PbZrO₃), PbTiO₃, BaTiO₃, BLSF (bismuth layer-structured ferromagnetic), KNbO₃—NaNbO₃, BiFeO₃, (Bi,Na)TiO₃, Bi(Zn,Ti)O₃ or the like and their solid solutions.

For example, in the case where the thin-film part has the positive piezoelectric effect or the inverse piezoelectric effect, the thin-film part is preferably composed of the piezoelectric body out of the above described materials. Moreover, in the case where the thin-film part has the function of the accumulation of electric charges, the thin-film part is preferably composed of the dielectric body out of the above-described materials.

Therefore, for example, in the case of making the thin-film part(s) of the first thin-film element 23 and/or the second thin-film element 24 have any function selected from the positive piezoelectric effect, the inverse piezoelectric effect and the electric charge accumulation, the first thin-film part 231 and/or the second thin-film part 241 can be made to be a piezoelectric body or a dielectric body. Then, for the piezoelectric body or the dielectric body, lead zirconate titanate or barium titanate can be preferably used.

Accordingly, for example, the first thin-film part 231 and/or the second thin-film part 241 can include lead zirconate titanate (PZT). Moreover, the first thin-film part 231 and/or the second thin-film part 241 can also include barium titanate. Meanwhile, since materials of the thin-film parts formed on the substrate are not necessarily the same, the materials of the first thin-film part 231 and of the second thin-film part 241 may be different.

In the case where the thin-film part has the function of semiconductivity, the thin-film part is preferably composed of the oxide semiconductor out of the above described materials. In the case where the thin-film part has the function of conductivity, the thin-film part is preferably composed of the conductive oxide out of the above described materials. Meanwhile, the thin-film part is not necessarily made of a single kind of material, but may include plural materials.

Moreover, the thin-film part included in the thin-film element is not limited to be a single layer, but may be configured to have plural layers. Specifically, for example, in the case where the thin-film part has the function of semiconductivity and the thin-film element is a diode, the thin-film part can have a configuration in which a p-type semiconductor layer composed of ZnO and an n-type semiconductor layer composed of IGZO are laminated. Meanwhile, in the case where the thin-film part included in the thin-film element has a configuration of plural layers, a thickness of an entire thin-film part in which plural layers are laminated is a film thickness of the thin-film part.

Moreover, upon forming the thin-film part, in order to control a crystalline orientation of the thin-film part, in a lower layer part of the thin-film part a seed layer may be provided.

In the electronic device according to the present embodiment, the plural thin-film elements are included as described above, and each of the plural thin-film elements has a thin-film part. That is, each of the thin-film elements has the thin-film part provided with a specific function. Then, a thickness of the thin-film part included in each of the thin-film element can be made to be an optimum thickness according to the function or a characteristic of each of the thin-film elements. Accordingly, for example, in the case of the electronic device 20 shown in FIG. 2, thicknesses of the first thin-film part 231 of the first thin-film element 23 formed on the substrate 21 and of the second thin-film part 241 of the second thin-film element 24 can be made different. Meanwhile, in the case where the electronic device includes three or more thin-film elements, all the thicknesses of the thin-film parts of the thin-film elements may be different, and the thicknesses of the thin-film parts of a part of the thin-film elements out of the configuring thin-film elements may be the same.

A method of forming the thin-film part included in the thin-film element formed on the substrate is not particularly limited, and it can be formed by an arbitrary method so as to have desired thickness and shape.

The thin-film part may be formed by, for example, applying a precursor solution of a sol-gel liquid or the like by a printing method to form a precursor thin film, and by giving energy to the precursor thin film. In the case of the electronic device shown in FIG. 2, the first thin-film part 231 and the second thin-film part 241 can be formed by, for example, applying the precursor solution by the printing method to form a precursor thin film (a first precursor thin film and a second precursor thin film), and by giving energy to the precursor thin film.

The precursor solution means a solution which provides a desired composition of a thin-film part by performing energy deposition. It varies according to a material or a composition required for the thin-film part, and it is not particularly limited.

In the case where the thin-film part includes, for example, PZT (lead zirconate titanate), lead acetate, zirconium alkoxide and titanium alkoxide can be starting materials, and a precursor solution of PZT, which is dissolved in a common solvent 2-methoxy-ethanol and made uniform, can be preferably used.

The PZT is a solid solution of lead zirconate (PbZrO₃) and lead titanate (PbTiO₃), and represented by a chemical formula Pb(Zr₁₋ₓTiₓ)O₃ where x is greater than zero and less than one. According to the ratio the characteristic varies. In general, the composition that provides excellent electric and mechanical properties is a composition where the molar ratio of PbZrO₃ to PbTiO₃ is 53 to 47. This composition is represented by a chemical formula Pb(Zr_{0.53}Ti_{0.47})O₃, and is generally denoted by PZT(53/47). Accordingly, the starting materials, i.e. lead acetate, zirconium alkoxide and titanium alkoxide are preferably weighed and mixed so as to be the stoichiometric proportion of the chemical formula.

Meanwhile, energy is given to the precursor thin film on which the precursor solution is applied. In the case where the precursor thin film includes Pb, upon giving energy, a part of Pb atoms in the precursor thin film may be vaporized, i.e. a so-called lead-free condition may occur. Accordingly, in the case of preparing a complex oxide such as PZT including lead, Pb of 5 to 25% in mass ratio compared with the stoichiometric composition is preferably added to the starting materials excessively, assuming the lead-free condition upon giving energy.

Moreover, since metallic alkoxide compound is susceptible to hydrolysis by atmospheric moisture, progress of the hydrolysis is preferably inhibited by adding a proper quantity of acetylacetone, acetic acid, diethanolamine or the like as a stabilizer to the precursor solution.

A material preferably used for the thin-film part includes as a piezoelectric body other than the PZT, for example barium titanate or the like. In the case of barium titanate for the thin-film part, it is also possible to prepare a precursor solution for barium titanate by using barium alkoxide or titanium alkoxide as a starting material and dissolving these materials in the common solvent.

A concentration of the precursor solution to be used is not especially limited, and the concentration of the precursor solution may be arbitrarily selected according to the material or the film thickness of the thin-film part to be formed, a printing method to be used, an energy imparting means in an energy imparting process or the like.

For example, the film thickness of the thin-film part to be formed may be controlled by changing the concentration of the precursor solution to be provided. For example in the case where in the electronic device 20 in FIG. 2 film thicknesses of the first thin-film part 231 and of the second thin-film part 241 are different from each other, the concentration of the precursor solution used for the formation of a first precursor thin-film may be different from the concentration of the precursor solution used for the formation of a second precursor thin-film.

A location at which the precursor solution is applied is not especially limited. The precursor solution may be applied at an arbitrary location where a thin-film element is formed on the substrate with an arbitrary area and an arbitrary shape. Meanwhile, according to a configuration of the thin-film element an electrode, a seed layer, a barrier layer or the like may be provided between the substrate and the thin-film part. Accordingly, it is not limited to the case of applying the precursor solution directly on the substrate, but the precursor solution may be applied on a top side of the electrode, the seed layer, the barrier layer or the like. Moreover, in the case of laminating plural layers of the precursor thin-films, the precursor solution may be applied on the top side of the precursor thin-film which is formed previously.

Moreover, also the printing method is not especially limited. It may be a method of applying the precursor solution at a predetermined location on the substrate. For the printing method for example an offset method, a screen printing method, an inkjet method or the like may be preferably used. Most of all, for the printing method the inkjet method can be preferably used. In the inkjet method a printing plate is not required and an arbitrary pattern can be easily formed in each lot. Moreover, a consumption amount of the precursor solution can be suppressed since the precursor solution is necessarily provided only to a part where a precursor thin-film is formed.

In the case of using the inkjet method for the printing method, the film thickness of the thin-film part can be controlled also by changing an application density of the application of the precursor solution in a region where the thin-film part is formed. For example, in the case where in FIG. 2 film thicknesses of the first thin-film part 231 and of the second thin-film part 241 are different from each other, the application density of the precursor solution upon forming the first precursor thin-film may be different from the application density of the precursor solution upon forming the second precursor thin-film.

Here, changing the application density upon applying the precursor solution will be explained with reference to FIG. 3.

FIGS. 3A and 3B illustrate states after the precursor solution is applied in a thin-film part formation region 31 surrounded by a rectangle in the drawings.

Then, FIG. 3A illustrates an example where liquid drops 32 of the precursor solution are provided by the inkjet method so as to overlap each other within a range of a length of a radius of the liquid drop 32 in the thin-film part formation region 31. Meanwhile, a distance between liquid drops generally varies according to the inkjet apparatus and is not limited to the above configuration. In the case shown in FIG. 3A, the liquid drops 32 of the precursor solution are applied in the thin-film part formation region 31 seven drops in the vertical direction in the drawing and eight drops in the horizontal direction.

In FIG. 3B, liquid drops 32 of the precursor solution are provided by the inkjet method to the thin-film part formation region 31 which is the same size and the same shape as that in FIG. 3A. However, in FIG. 3B compared with FIG. 3A liquid drops are applied while thinning out a part of the liquid drops so that the liquid drops are separated by two lines in the vertical direction of the thin-film part formation region 31. Accordingly, the liquid drops 32 of the precursor solution are applied in the thin-film part formation region 31 three drops in the vertical direction and eight drops in the horizontal direction. The provision of the liquid drops of only one row (line) out of three rows (lines) as above will be denoted “thinning of ⅓” in the following.

Then, changing the application density of the precursor solution means changing a density of liquid drops provided in the thin-film part formation region when the liquid drops of the precursor solution are supplied to and applied on the thin-film part formation region by the inkjet method as shown in FIG. 3A and FIG. 3B.

As described above, by changing the application density of the precursor solution a quantity of the precursor solution supplied to the thin-film part formation region can be changed. Then, since there is a correlation relation between the quantity of the precursor solution supplied to the thin-film part formation region and a thickness of the thin-film part which is formed, it is possible to control the film thickness of the thin-film part by changing the application density of the precursor solution as described above.

Meanwhile, as an example of supplying the liquid drops while thinning out a part of them, the example of supplying at intervals in the vertical direction is illustrated in FIG. 3B. However, the present invention is not limited to this example. In FIG. 3B, for example, the liquid drops may be supplied at intervals in the horizontal direction. Moreover, in FIG. 3B the liquid drops are supplied while two rows out of three rows are thinned out. The present invention is not limited to this example. The degree of thinning out may be arbitrarily selected.

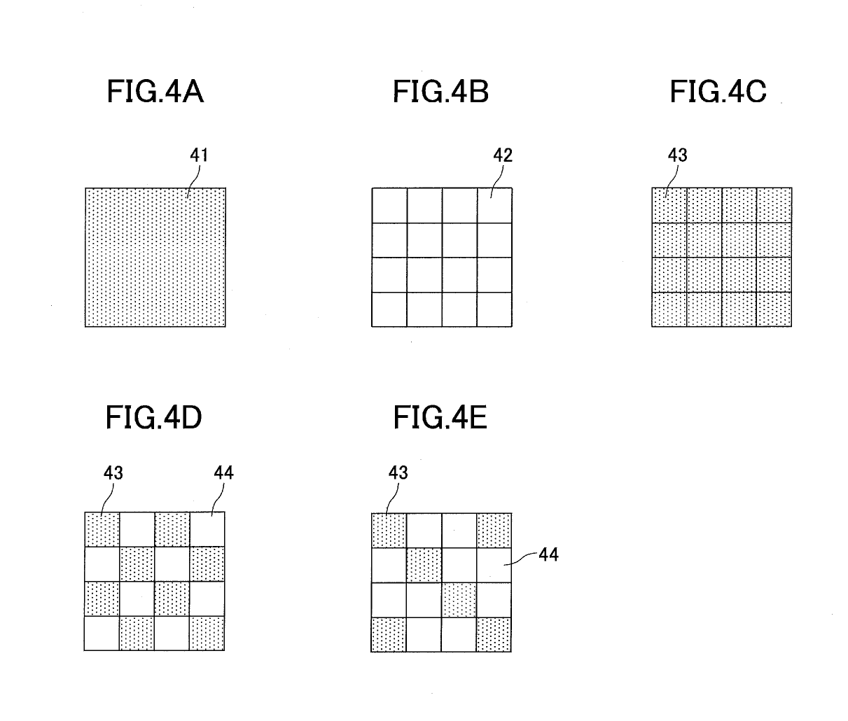

A method of forming thinning data for supplying liquid drops of the precursor solution while thinning out as above will be explained with reference to FIG. 4.

In the case of printing by a normal printing apparatus, an image as a base is converted into a bitmap and based on the bitmap liquid drops of ink or the like are supplied, and thereby an image is formed.

Then, a print pattern as a base is shown in FIG. 4A. In FIG. 4A, a pattern where printing is performed in an entire region 41 surrounded by a rectangle is shown.

Then, when the print pattern shown in FIG. 4A is converted into a bitmap, it is divided into plural pixels 42 as shown in FIG. 4B. A number of divided pixels, for example, depends on the print apparatus or the like, and is not limited particularly. An explanation will be given in the following using an example of dividing into pixels of 4 in the vertical direction and 4 in the horizontal direction.

Then, in the case of supplying liquid drops of the precursor solution to all pixels according to the formed bitmap, as shown in FIG. 4C supply data of the liquid drops can be prepared. In FIG. 4C all pixels are pixels 43 which receive liquid drops, where for each of the pixels a liquid drop is supplied. In this case a thinning out rate is zero. This corresponds to FIG. 3A as described above.

Moreover, in the case of a thinning of ½, for example as shown in FIG. 4D, thinning data for the liquid drops can be prepared. In FIG. 4D, a pattern can be formed including a pixel 43 that receives liquid drops of the precursor solution and a part 44 that does not receive liquid drops. Meanwhile, the thinning ½ means a method of thinning out by supplying liquid drops to only one row (line) out of two rows (lines).

Moreover, in the case of a thinning of ⅓, as shown in FIG. 4E thinning data for the liquid drops can be prepared. Also in FIG. 4E, a pattern includes the pixel 43 that receives liquid drops of the precursor solution and the part 44 that does not receive liquid drops. Meanwhile, the pixel 43 that receives liquid drops of the precursor solution and the part 44 that does not receive liquid drops may be arranged in a checkerboard pattern as shown in FIG. 4E. However, a pattern as shown in FIG. 3B may be employed.

For example, in the case of the thinning of ⅓, compared with the case where the thinning out rate is zero, the quantity of the supplied precursor solution is about one third and the film thickness of the obtained thin-film part is about one third of that of the case where the thinning out rate is zero.

A number of times of applying the precursor solution on a part where the thin-film part is formed by using a printing method upon forming the thin-film part is not particularly limited. It can be arbitrarily selected according to the film thickness or the like of the thin-film part to be formed. For example, in the case where film thicknesses of the first thin-film part 231 and of the second thin-film part 241 are different from each other, a number of times of applying the precursor solution on a region where the first thin-film part is formed may be different from a number of times of applying the precursor solution on a region where the second thin-film part is formed. In the case where the numbers of times of application for the first thin-film part 231 and for the second thin-film part 241 are different from each other, the quantity of the precursor solution supplied to the formation region of each of the thin-film parts varies and the film thicknesses of the obtained thin-film parts are different.

As described above, a precursor thin-film can be formed by applying the precursor solution. Then, the precursor thin-film becomes a thin-film part by imparting energy by the energy imparting means.

The energy imparting means is preferably a means for imparting energy to a precursor thin-film part by drying the precursor thin-film part formed by applying the precursor solution or in some cases further performing heat decomposition or crystallization, although it is not particularly limited. The energy imparting means includes a resistive heater such as a heater, a heating means using a microwave, a heating means using laser light or the like.

A condition upon imparting energy to the precursor thin-film is not particularly limited. However, the solvent included in the precursor thin-film is removed by drying and furthermore an organic substance included in the precursor solution is preferably heat-decomposed. Especially the process preferably proceeds to the crystallization so that the material included in the thin-film part is crystallized and sufficient performance is provided.

Since a condition for drying, heat-decomposing or crystallizing for the precursor thin-film by imparting energy varies according to a kind of precursor solution or the like, it is not particularly limited and can be arbitrarily selected.

As described above, in the case of performing the application of the precursor solution plural times, timing or a number of times of imparting energy is not particularly limited. For example, every time the precursor solution is applied the precursor thin-film may be dried, heat-decomposed and crystallized by imparting energy by the energy imparting means. Moreover, every time the precursor solution is applied the precursor thin-film may be dried by the energy imparting means. Furthermore, every time the precursor solution is applied several times the precursor thin-film may be heat-decomposed and crystallized by the energy imparting means.

Meanwhile, in the case of heating the precursor thin-film by the energy imparting means, the entire electronic device including the substrate may be heated. Moreover, the precursor thin-film formed by applying a precursor may be selectively heated.

As described above, the electronic device according to the present embodiment has been explained. According to the present embodiment, an electronic device provided with plural thin-film elements where the film thicknesses of the thin-film parts of the thin-film elements are different from each other can be provided. Accordingly, downsizing of the apparatus or reducing the cost is achieved.

Next, an example of a manufacturing method of the electronic device according to the present embodiment will be explained.

The present embodiment relates to a method for manufacturing an electronic device including a substrate, a first thin-film element formed on the substrate and provided with a first thin-film part and a second thin-film element formed on the substrate and provided with a second thin-film part wherein film thicknesses of the first thin-film part and the second thin-film part are different. Then, the manufacturing method may include the following processes:

a first precursor thin-film formation process that forms a first precursor thin-film by applying the precursor solution by the printing method;

a second precursor thin-film formation process that forms a second precursor thin-film by applying the precursor solution by the printing method; and

an energy imparting process that forms the first thin-film part and the second thin-film part by imparting energy to the first precursor thin-film and the second precursor thin-film.

In the following the first precursor thin-film formation process and the second precursor thin-film formation process in the method for manufacturing the electronic device according to the present embodiment will be explained as follows.

The electronic device according to the present embodiment may include plural thin-film elements provided on the substrate 21 as shown in FIG. 2.

Then, the first precursor thin-film formation process and the second precursor thin-film formation process may be performed, for example, by applying the precursor solution on the substrate 21 shown in FIG. 2 so as to fit a desired shape.

Meanwhile, as described above, a location at which the precursor solution is applied is not particularly limited. The precursor solution may be applied at an arbitrary location where the thin-film element is formed on the substrate with an arbitrary area and an arbitrary shape. Moreover, according to a configuration of the thin-film element, an electrode, a seed layer, a barrier layer or the like may be provided. Accordingly, it is not limited to the case where the precursor solution is applied directly on the substrate but the precursor solution may be applied on a top side of the electrode, the seed layer, the barrier layer or the like. Moreover, in the case of laminating plural layers of the precursor thin-film, the precursor solution may be applied on a top side of the previously formed precursor thin-film.

The precursor solution in the manufacturing method for the electronic device according to the present embodiment means a solution that provides a desired composition of the thin-film part by imparting energy. Since it varies according to the material of the thin-film part or the composition, it is not particularly limited.

A concentration of the precursor solution to be used is not especially limited, and the concentration of the precursor solution may be arbitrarily selected according to the material or the film thickness of the thin-film part to be formed, a printing method to be used, an energy imparting means in an energy imparting process or the like.

For example, the film thickness of the precursor thin-film to be formed or furthermore the thin-film part may be controlled by changing the concentration of the precursor solution to be provided according to the film thickness of the thin-film part to be formed. That is, in the first precursor thin-film formation process and the second precursor thin-film formation process a concentration of the precursor solution used for the formation of the first precursor thin-film may be different from a concentration of the precursor solution used for the formation of the second precursor thin-film.

To explain it with the example of the electronic device shown in FIG. 2, in the case of making the film thickness of the first thin-film part 231 greater than that of the second thin-film part 241 the concentration of the precursor solution to be provided to the first thin-film part 231 may be greater than the concentration of the precursor solution to be provided to the second thin-film part 241.

Though a printing method in the precursor thin-film formation process is not particularly limited as described above, for example, an offset method, a screen printing method, an inkjet method or the like may be preferably used. Above all the inkjet method is more preferably used for the printing method.

In the case of using the inkjet method for the printing method by changing an application density for applying the precursor solution in the region where the thin-film part is formed, the film thickness of the thin-film part can be controlled. That is, in the first precursor thin-film formation process and the second precursor thin-film formation process an application density of the precursor solution upon forming the first precursor thin-film may be different from an application density of the precursor solution upon forming the second precursor thin-film. For example, in FIG. 2 in the case of making the film thickness of the first thin-film part 231 greater than the film thickness of the second thin-film part 241, the application density of the precursor solution to be applied in the region where the first thin-film part 231 is formed may be greater than the application density of the precursor solution to be applied in the region where the second thin-film part 241 is formed.

Since the application density has already been explained, here an explanation will be omitted.

Upon forming the thin-film part, a number of times the precursor solution is applied by the method of printing on a part where the thin-film part is formed is not particularly limited and is arbitrarily selected according to the film thickness of the thin-film part to be formed or the like. For example, upon manufacturing the electronic device shown in FIG. 2, the first precursor thin-film formation process and/or the second precursor thin-film formation process may be conducted plural times. Then, since it can be conducted repeatedly by the number of times according to the film thickness of each of the thin-film parts, the number of times conducting the first precursor thin-film formation process may be different from the number of times conducting the second precursor thin-film formation process.

For example, in the case where the film thickness of the first thin-film part 231 is greater than the film thickness of the second thin-film part 241, the first precursor thin-film formation process may be conducted more times than the second precursor thin-film formation process.

Next an energy imparting process will be explained.

The energy imparting process is a process of imparting energy to the first precursor thin-film part and the second precursor thin-film part, drying the precursor thin-film which is formed and in some cases further performing heat decomposition or crystallization. The energy imparting means is not particularly limited, and for the energy imparting means a resistive heater such as a heater, a heating means using a microwave, a heating means using laser light or the like may be used. The temperature for heating is not particularly limited. It may be arbitrarily selected according to the kind of the precursor solution to be used or the like.

For example, in the case of conducting the energy imparting process plural times the condition for imparting energy does not have to be constant and the energy imparting condition may be arbitrarily changed.

For example, it includes an energy imparting process with a condition of drying the precursor thin-film (it will be denoted “drying process” in the following). Moreover, it includes an energy imparting process with a condition of heat-decomposing an organic substance included in the precursor thin-film (it will be denoted “heat decomposition process” in the following) and an energy imparting process with a condition of crystallizing the precursor thin-film (it will be denoted “crystallization process” in the following.

In order to convert the precursor thin film into a thin-film part a component added for forming a solution is preferably removed by the drying process or the heat decomposition process. Then, in order to improve especially the performance of the thin-film part, a component in the thin-film part is preferably crystallized by the crystallization process. Since a specific condition for each of the processes varies according to the component included in the precursor solution or the material included in the thin-film part, it is not particularly limited.

As described above, in the case of conducting the first and/or second precursor thin-film formation process (it will be denoted “precursor thin-film formation process” in the following plural times, the precursor thin-film formation process and the energy imparting process may be repeatedly conducted with an arbitrary combination.

For example, every time the precursor thin-film formation process is conducted, that is every time the precursor thin-film is formed, all processes of the drying process, the heat decomposition process and the crystallization process also may be conducted.

Moreover, as the other combination, every time the precursor thin-film formation process is conducted the drying process is conducted and further every time the precursor thin-film formation process is conducted several times the heat decomposition process or the crystallization process may be conducted.

Meanwhile, in the case where the precursor thin-film formation process is conducted only once the condition for the energy imparting process may be arbitrarily selected in response to a characteristic required for the thin-film part. However, in order to improve the performance of the thin-film part the drying process, the heat decomposition process and the crystallization process are all preferably conducted.

In the case of heating the precursor thin-film by the energy imparting process the entire electronic device including the substrate may be heated. Moreover, a precursor thin-film formed by applying the precursor may be selectively heated.

Moreover, in the manufacturing method of an electronic device according to the present embodiment an arbitrary process may be added to the above-described precursor thin-film formation process and the energy imparting process.

As described above, since a printing method is used in the precursor thin-film formation process it is possible to apply the precursor solution only at a desired location and form a precursor thin-film. However, for example, in the case of using the inkjet method for the printing method so as to apply the precursor solution only at the location where the thin-film part is formed more definitely, a substrate surface reformulation process for reforming a surface of the substrate may be conducted before the precursor thin-film formation process.

A configuration example for the substrate surface reformulation process will be explained in the following.

The substrate surface reformulation process specifically may be, for example, to form a SAM (Self Assembled Monolayer) film which is a hydrophobic film on a part where a thin-film part is not formed on the substrate so that the precursor solution is applied only on a part where the thin-film part is formed. In the case of forming the SAM film for the substrate, a platinum plate or a substrate on a surface of which a platinum film is formed is preferably used.

The SAM film may be formed, for example, by applying a SAM material including alkanethiol on the substrate. It is not particularly limited to the alkanethiol but a material having a molecule in which a carbon chain is C6 to C18, for example, is preferably used. Then, a solution in which this material is dissolved in a general organic solvent such as alcohol, acetone, toluene or the like is preferably used as the SAM material.

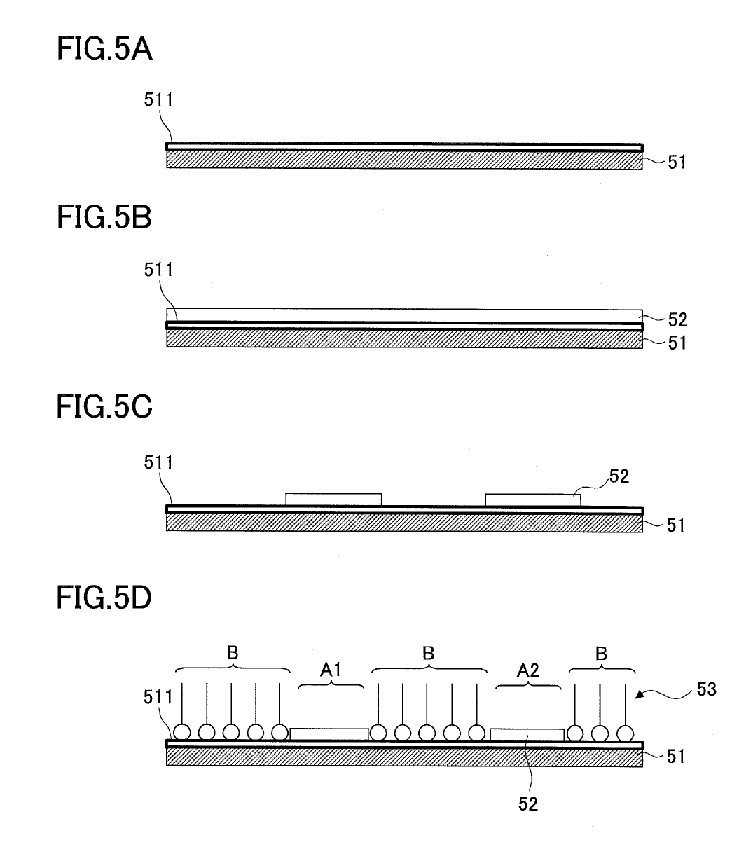

A configuration example for a method of manufacturing plural thin-film elements in the case of conducting the process of reforming the substrate surface will be explained with reference to FIGS. 5A to 5D.

At first as shown in FIG. 5A, a substrate 51 is prepared. On at least one side of the substrate 51 a platinum film 511 is preferably formed. Accordingly, as the substrate 51 a platinum plate or a substrate in which a platinum film is formed on a surface of various substrates such as a Si substrate may be preferably used. In the case of using the substrate in which a platinum film is formed on a surface of the Si substrate or the like the platinum film may also be used as a lower electrode.

Next, as shown in FIG. 5B, a layer of a ceramics film 52 is formed on top side of the surface of the substrate 51 where the platinum film 511 is formed. Next, as shown in FIG. 5C the ceramics film 52 is patterned so as to fit a shape of the thin-film part. Accordingly, an outermost surface part on the substrate 51 may include a part where the platinum film 511 is exposed and a part where the ceramics film 52 is exposed.

A method of forming the ceramics film 52 is not particularly limited, but for example, a precursor solution for the ceramics film 52 is applied on the top side of the substrate 51 by a spin coating method to form a coated film on a whole surface of the substrate 51. Then, by conducting processes of drying and heat-decomposing the coated film, the ceramics film 52 is formed. Also a method of patterning the ceramics film 52 is not particularly limited. For example a photoresist pattern is formed at a desired site by a photolithography method and afterwards patterning may be performed by dry etching or wet etching. And then, photoresist may be removed.

Meanwhile, in this case a material for the ceramics film 52 is not particularly limited but it is preferably the same material as the thin-film part to be formed. Accordingly, the precursor solution to be used in the precursor thin-film formation process may be preferably used.

Moreover, the ceramics film 52 may also form an electrode of the thin-film element. In the case of using the ceramics film 52 as the electrode of the thin-film element, the ceramics film may be a film of lanthanum nickel oxide, strontium ruthenium oxide or the like.

Next, the substrate is immersed in a solution of the above described SAM material. After a predetermined time period the substrate is taken out and surplus molecules are displaced and washed by solvent and dried; thereby a SAM film 53 is formed on the surface of the substrate 51 as shown in FIG. 5D. Since the SAM film 53 is formed selectively only on a surface of the platinum film 511, it is not formed on a surface of the ceramics film 52. For this reason, on the surface of the substrate 51 a part “B” on which the SAM film 53 is formed becomes hydrophobic and parts “A1”, “A2” on which the SAM film 53 is not formed become hydrophilic. Accordingly, in the case of applying the precursor solution by the ink jet method the precursor solution is supplied selectively only to the parts “A1”, “A2” in FIG. 5D and it becomes possible to form a thin-film part having a desired shape more definitely, which is desirable.

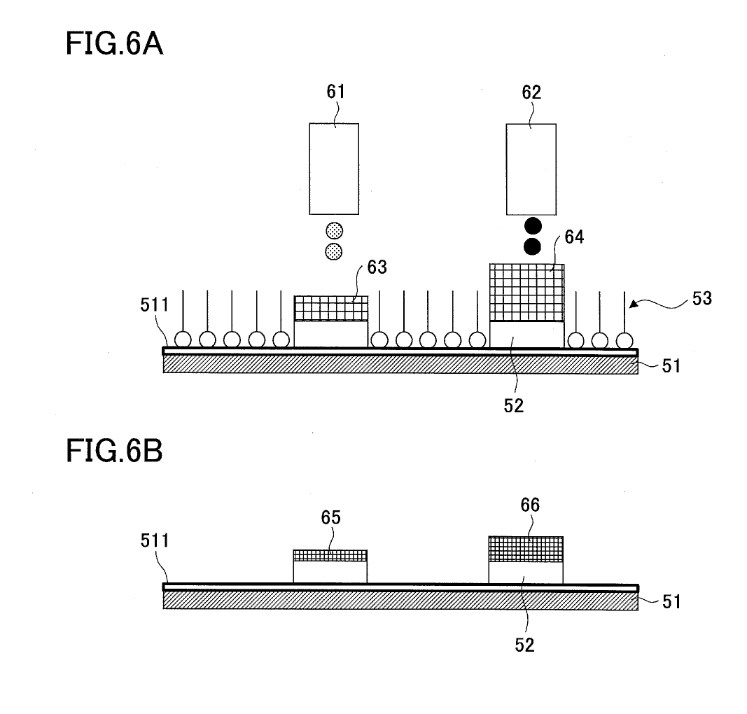

Then, after the process of reforming the substrate surface shown in FIG. 5D a process of forming the above described plural thin-film elements is conducted. For example, as shown in FIG. 6A, by a liquid drop discharge head provided with multiple nozzles 61, 62, a precursor solution which is a raw material of the thin-film part is applied on the hydrophilic parts “A1”, “A2” and a first precursor thin-film 63 and a second precursor thin-film 64 are formed, respectively. Afterwards the energy imparting process of drying solvent of the precursor thin-films, or heat-decomposing, crystallizing or the like is performed, as shown in FIG. 6B, so that a first layer 65 of a first thin-film element and a first layer 66 of a second thin-film element can be formed on the ceramics film 52.

Meanwhile, in the case of conducting the precursor thin-film formation process plural times, the process of reforming the substrate surface is preferably conducted again after the energy imparting process and before conducting the precursor thin-film formation process. After the first energy imparting process ends when it is washed by isopropyl alcohol, for example, a configuration in which an outermost surface part on the substrate includes a part where the platinum film 511 is exposed and a part where the ceramics film 52 is exposed appears as shown in FIG. 5C. For this reason by immersing the substrate 51 in the solution of the SAM material again, after a predetermined time period taking it out, displacing and washing surplus molecules by solvent and drying the substrate 51, the SAM film 53 can be formed on the surface of the substrate 51 as shown in FIG. 5D.

From here by repeatedly conducting the respective processes arbitrarily a thin-film element including a thin-film part having a desired film thickness can be formed.

A method of reforming the substrate surface is not limited to the above method.

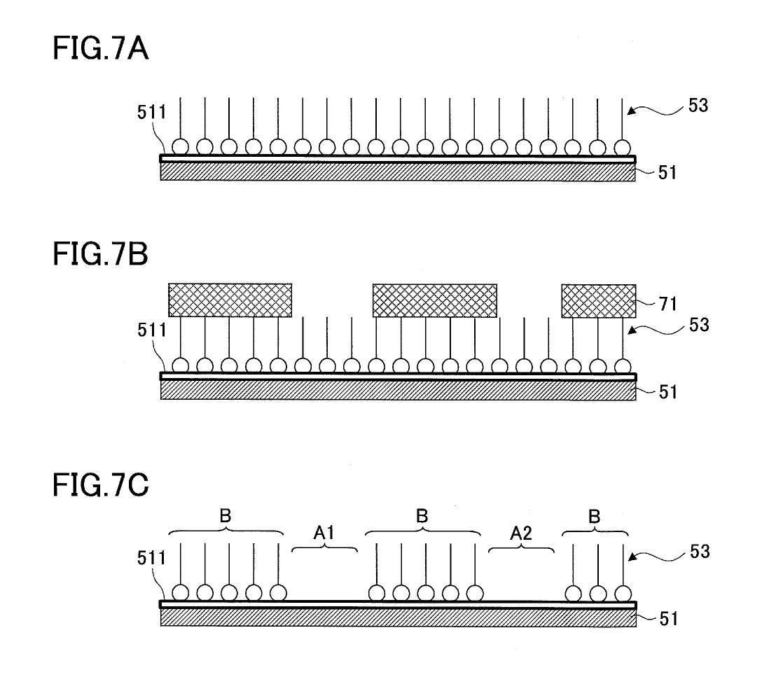

A second method of reforming the substrate surface will be explained with reference to FIGS. 7A to 7C.

For example, after the stage shown in FIG. 5A, by immersing the substrate 51 on which the platinum film 511 is formed in the solution of the SAM material, taking out after a predetermined time period, displacing and washing surplus molecules by solvent and drying, the SAM film 53 can be formed on the surface of the substrate 51 as shown in FIG. 7A.

Next as shown in FIG. 7B, by a photolithography method a photo resist 71 having an aperture at a part where a thin-film element is to be formed is patterned. Then, as shown in FIG. 7C the SAM film 53 is removed by a dry etching and further the photo resist 71 used for the processing is also removed and the patterning of the SAM film 53 ends. Accordingly, as shown in FIG. 7C, on the surface of the substrate 51 a part “B” where the SAM film 53 remains is hydrophobic and parts “A1”, “A2” where the SAM film 53 is removed are hydrophilic. Afterwards, by conducting a process of forming plural thin-film elements as described above as shown in FIGS. 6A and 6B, a first thin-film element and a second thin-film element can be formed.

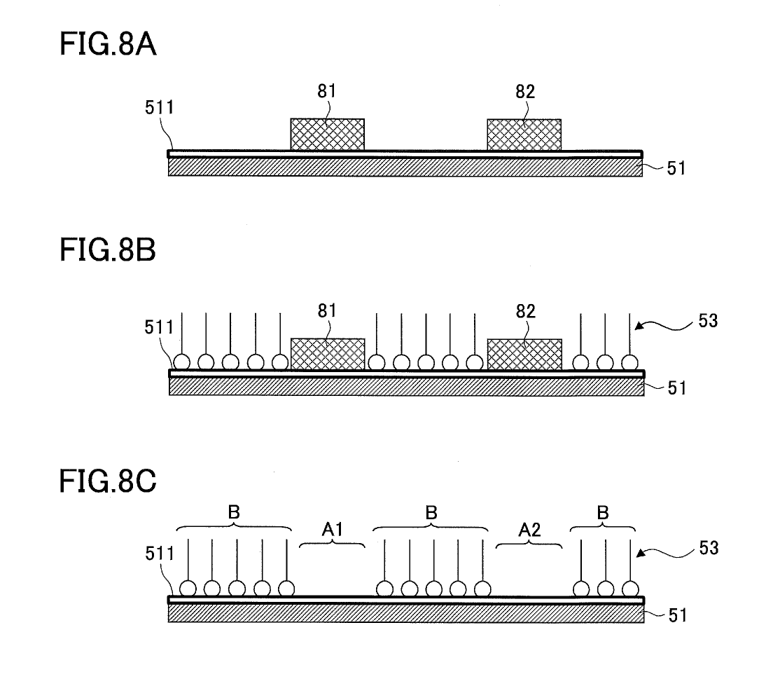

A third method of reforming the substrate surface will be explained with reference to FIGS. 8A to 8C. A member with the same reference numeral as that in FIGS. 5A to 5D indicates the same member.

First, as shown in FIG. 8A a photo resist pattern is formed by using the photo resists 81, 82 on the surface of the substrate 51 on which the platinum film 511 is formed, and the SAM film 53 is formed as shown in FIG. 8B. In this case, on the parts of the photo resist 81, 82 which is hydrophobic the SAM film is not formed but only on the other parts the SAM film can be formed. Then, as shown in FIG. 8C, by removing the photo resist 81, 82 the patterning of the SAM film 53 is completed and the processing of reforming the substrate surface is completed. Afterwards, by conducting the process of forming the plural thin-film elements as described above as shown in FIGS. 6A and 6B, the first thin-film element and the second thin-film element can be formed.

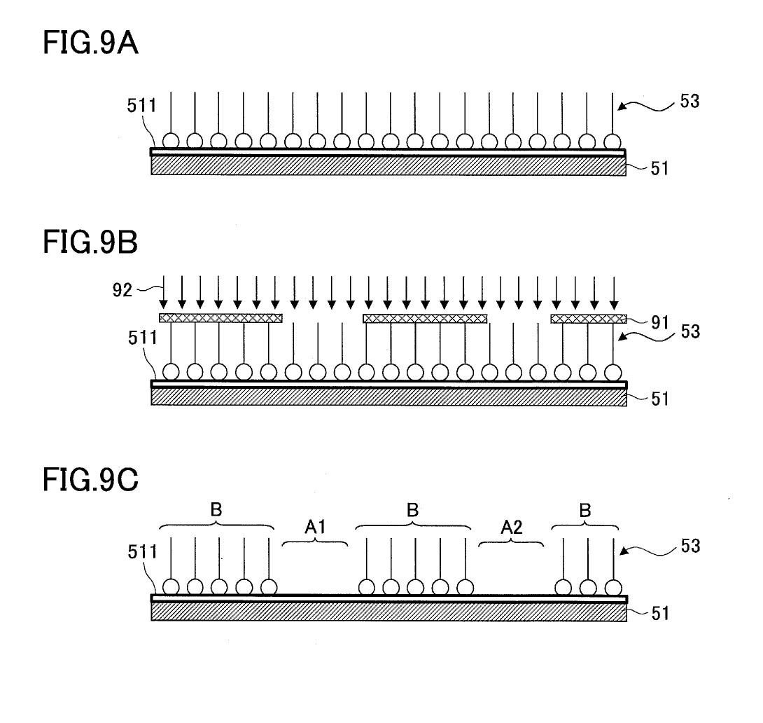

Next a fourth method of reforming the substrate surface will be explained with reference to FIGS. 9A to 9C. A member with the same reference numeral as that in FIGS. 5A to 5D indicates the same member.

First, as shown in FIG. 9A, a SAM film 53 is formed on the surface of the substrate 51 on which the platinum film 511 is formed. Then, as shown in FIG. 9B, by emitting ultraviolet light 92 via a patterned mask 91 as shown in FIG. 9C on an unexposed part, the SAM film 53 remains and from an exposed part the SAM film 53 disappears. Accordingly, the patterning of the SAM film 53 is completed and the processing of reforming the substrate surface is completed. Afterward, by conducting the process of forming the plural thin-film elements as described above as shown in FIGS. 6A and 6B the first thin-film element and the second thin-film element can be formed.

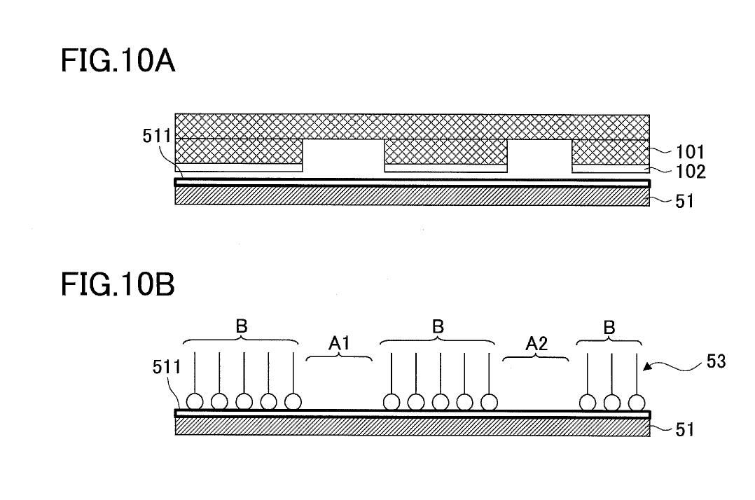

Next a fifth method of reforming the substrate surface will be explained with reference to FIGS. 10A and 10B. A member with the same reference numeral as that in FIGS. 5A to 5D indicates the same member.

First, as shown in FIG. 10A by a so-called micro contact print method on a PDMS stamp 101 which is patterned preliminarily by soft lithography or the like, a solution 102 which forms the SAM film is formed by immersion or by the spin coating method. Then, by performing a contact print for the PDMS stamp 101 on the substrate 51 on which the platinum film 511 is formed as shown in FIG. 10B, a patterned SAM film 53 is formed on the substrate 51. Accordingly, the processing of reforming the substrate surface is completed and afterwards by conducting the process of forming the plural thin film elements as shown in FIGS. 6A and 6B, the first thin-film elements and the second thin-film elements can be formed.

According to the manufacturing method for an electronic device as described above in the present embodiment, an electronic device provided on a substrate with plural thin-film elements, film thicknesses of which are different from each other, can be manufactured. Moreover, since the thin-film element is formed by a method of printing, material to be discarded is suppressed and cost can be reduced and the productivity can be increased.

### EXAMPLE

An example will be explained specifically in the following. However, the present invention is not limited to the example.

### First Example

According to the following procedure an electronic device provided with two piezoelectric elements which are thin-film elements on a substrate is manufactured.

First, the substrate and precursor solution are prepared according to the following procedure.

(Substrate Preparation Processing)

First, by thermally oxidizing a Si wafer a thermally-oxidized film (SiO₂ film) with a film thickness of 1000 nm is formed.

Next, in order to enhance an adhesiveness of a platinum film which will be described later with the thermally-oxidized film by reactive sputtering, a TiO₂ film with a film thickness of 50 nm is formed on a whole surface of one side of the substrate on which the thermally-oxidized film is formed.

Then, on the TiO₂ film by a sputtering method a platinum film with a film thickness of 200 nm is formed. Meanwhile, the platinum film becomes a lower electrode of the thin-film element.

The substrate on which the thermally-oxidized film (SiO₂ film), the TiO₂ film and the platinum film are formed on the surface of the Si wafer as described above is used for the processing in the following.

(Ceramics Film Formation Processing)

A ceramics film formation processing is conducted for forming a ceramics film on a part where the thin-film element is formed on the surface of the substrate where the platinum film is formed.

As shown in FIG. 5B, first a LaNiO₃ film (in the following it is also denoted “LNO film”) which is a conductive ceramics film is formed as a ceramics film 52 on the side of the substrate 51 on which the platinum film 511 is formed.

An application processing of applying by the spin coating method using a spin film formation solution of La₂O₃ and NiO (by Kojundo Chemical Laboratory Co., Ltd.) is conducted on the side of the substrate where the platinum film is formed.

Next, a crystallization processing of heating at 750° C., drying the spin film formation solution and crystallizing is performed.

The above application processing and the crystallization processing are repeated six times, and thereby an LNO film is formed.

Next, as shown in FIG. 5C the LNO film is patterned into a shape corresponding to two thin-film elements.

The patterning is performed by forming a resist with a desired shape by the photolithography method and further removing an unnecessary part of the LNO film by an etching method.

The etching is performed by using dilute hydrochloric acid solution.

By the patterning, two LNO films each of which has a shape with 0.5 mm square are formed on the substrate separated by a sufficient distance. The part where the two LNO films are formed is the formation region of the first and second thin-film elements.

(Precursor Solution Preparation Processing)

A precursor solution (sol-gel solution) is prepared so as to be a composition of PZT (53/47) i.e. Pb(Zr_{0.53},Ti_{0.47})O₃ after crystallization.

For the starting material of the precursor solution lead acetate trihydrate, titanium isopropoxide and zirconium isopropoxide are used. Crystallization water of lead acetate is dissolved in methoxyethanol and then is dehydrated. Meanwhile, a used amount of the starting material is adjusted so that a lead content is in excess by 10 mole percent with respect to the stoichiometric composition. Accordingly, a decrease in crystallinity due to insufficient lead in a heat treatment is prevented.

In the present example, precursor solutions for high concentration ink and for low concentration ink are prepared.

Each of the precursor solutions is obtained by dissolving titanium isopropoxide and zirconium isopropoxide in methoxyethanol, accelerating an alcohol exchange reaction and an esterification reaction and mixing with a methoxyethanol solution in which the lead acetate is dissolved.

Concentration is adjusted by adding methoxyethanol which is a main solvent so that a PZT concentration of the precursor solution which is the high concentration ink is 0.5 mol/l and a PZT concentration of the precursor solution which is the low concentration ink is 0.3 mol/l.

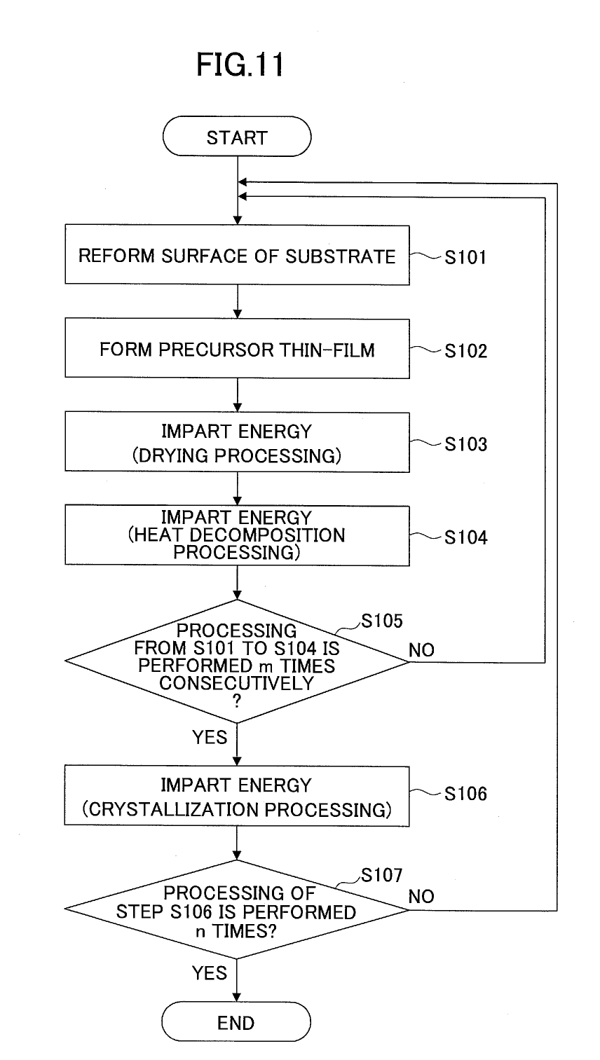

Next, an electronic device is manufactured by conducting repeatedly the respective processes as follows according to the flowchart shown in FIG. 11. Meanwhile, in the present example a number of times of repetition of the processes in the flowchart shown in FIG. 11 is assumed to be 3 for the determination step S105 (m=3) and 8 for the determination step S107 (n=8).

(Surface Reforming Processing)

A surface reforming processing (step S101) for forming a SAM film 53 in a part on the substrate 51 where an LNO film which is a ceramics film 52 is not formed is conducted.

For the material of the SAM film an alkanethiol (CH₃(CH₂)ₙ—SH) solution is used. Then, the surface reforming for the substrate is performed by forming the SAM film 53 on the surface of the substrate by displacing and washing surplus molecules by solvent and drying after immersing the substrate 51 in the alkanethiol solution.

(Precursor Thin-Film Formation Processing, Energy Imparting Processing)

First, according to the following procedures a precursor thin-film formation processing (step S102) for forming the precursor thin-film on the substrate is conducted.

The precursor solution is supplied on the substrate by the ink jet method using an industrial ink jet device in which an ink jet head manufactured by Ricoh Industry Company, Ltd. of type GEN4 is installed. The industrial ink jet device is provided with a nozzle with an integration of 300 dpi and can print with four kinds of ink at maximum output simultaneously. Moreover, because of mechanical scanning and discharge timing of the head, printing with a resolution of 2400 dpi in main scanning/sub scanning directions is possible and according to print information converted into a bit map, ink can be accurately discharged.

First, at a substrate alignment mark formed on the substrate in advance, a head nozzle position of the industrial ink jet device is fitted.

In the present embodiment, a precursor solution of 0.3 mol/l is provided to a formation region of a first thin-film element and a precursor solution of 0.5 mol/l is provided to a formation region of a second thin-film element. Meanwhile, these precursor solutions are the low concentration ink and the high concentration ink, respectively, which are prepared in the precursor solution preparation processing described as above.

The industrial ink jet device used in the present embodiment upon supplying the precursor solution as described above can discharge using position information of 2400 dpi, i.e., a distance X between droplets shown in FIG. 3B in units of 10.58 μm. However, in the present embodiment as shown in FIG. 3B the printing is performed with the “thinning of ⅓” where two rows are thinned out from three rows of information.

Next, the energy imparting processing is conducted.

The substrate on which the precursor solutions are applied in the formation regions for the first thin-film element and the second thin-film element is heat processed at 120° C. and solvent drying is performed (step S103) as the energy imparting processing (drying processing). Afterwards, as the energy imparting processing (heat decomposition processing) heat decomposition of an organic substance (about 500° C.) is further performed (step S104).

Meanwhile, in the following the energy imparting processing (drying processing) will be simply denoted also “drying processing”, and the energy imparting processing (heat decomposition processing) will be simply denoted also “heat decomposition processing”.

After the above drying processing (step S103), the substrate is washed with isopropyl alcohol.

Then, the processing from the surface reforming processing (step S101) to the heat decomposition processing (step S104) is repeated three times including the first processing described above.

After repeating the processing from step S101 to step S104 three times, the crystallization processing is performed at 700° C. (step S106) as the energy imparting processing (crystallization processing). Meanwhile, the energy imparting processing (crystallization processing) will be simply denoted also as “crystallization processing” in the following.

Then, when the processing from the surface reforming processing (step S101) to the heat decomposition processing (step S104) is repeated three times in total and the crystallization processing (step S106) is performed, a film thickness of a film part of the first thin-film element is 150 nm and a film thickness of a film part of the second thin-film element is 240 nm.

Meanwhile, when as a preliminary test the processing from the surface reforming processing (S101) to the heat decomposition processing (S104) is performed once and the crystallization processing (S106) is performed, the film thickness of the film part of the first thin-film element is 50 nm and the film thickness of the film part of the second thin-film element is 80 nm.

Afterwards, a flow of repeating the processing from the surface reforming processing (S101) to the heat decomposition processing (S104) three times and of performing the crystallization processing (S106) is repeated eight times in total including the first flow as described above. As a result the first thin-film element having the thin-film part with the film thickness of 1200 nm and the second thin-film element having the thin film part with the film thickness of about 2000 nm are obtained. Moreover, it is confirmed that a failure such as a crack does not occur in either the first or second thin-film element obtained as above.

Then, on the top sides of the first and second thin-film elements obtained as above, a platinum film with film thickness of 200 nm is formed as the upper electrode and the first thin-film element and the second thin-film element are obtained.

As described above, thin-film elements with different film thicknesses can be formed on the same substrate.

### Second Example

In the present example, a difference in a film thickness of a thin-film part according to a difference in a number of times repeating the precursor thin-film formation processing upon forming a thin-film part of a first thin-film element and a thin-film part of a second thin-film element will be examined.

In the present example, when the thin-film part of the first thin-film element and the thin-film part of the second thin-film element are formed the high concentration ink of 0.5 mol/l which is prepared in the first example as a precursor solution is used for both of the thin-film elements.

The first thin-film element is prepared in the same way as in the first example other than that the above-described high concentration ink is used for the precursor solution. As a result a thin-film element having the thin-film part with a film thickness of about 2000 nm is obtained.

Meanwhile, for the first thin-film element the thin-film part is formed by repeating eight times in total the flow of repeating the processing from the surface reforming processing (S101) to the heat decomposition processing (S104) three times and of performing the crystallization processing (S106). For this reason the precursor thin-film formation processing (S102) is performed 24 times in total.

For the second thin-film element the thin-film part is formed in the same way as the first thin-film element in the present example other than that the numbers of repetition of the precursor thin-film formation processing and of the energy imparting processing are different. When the second thin-film element is formed a number of times of repetition of the processes in the flowchart shown in FIG. 11 is assumed to be 3 for the determination step S105 (m=3) and 4 for the determination step S107 (n=4) and the process is conducted.

That is, for the second thin-film element the thin-film part is formed by repeating four times in total the flow of repeating the processing from the surface reforming processing (S101) to the heat decomposition processing (S104) three times and of performing the crystallization processing (S106). For this reason the precursor thin-film formation processing (S102) is performed 12 times in total.

Accordingly, after repeating four times the flow of repeating the processing from the surface reforming processing (S101) to the heat decomposition processing (S104) three times and of performing the crystallization processing (S106) for the thin-film part of the first thin-film element, the formation of the thin-film part of the second thin-film element starts.

As described above, for the thin-film part of the first thin-film element the precursor thin-film formation processing (S102) is conducted 24 times in total whereas for the thin-film part of the second thin-film element the precursor thin-film formation processing (S102) is conducted only 12 times in total.

As a result, the film thickness of the thin-film part of the first thin-film element obtained as above is 2000 nm, and the film thickness of the thin-film part of the second thin-film element is 1000 nm.

Then, on the top sides of the first and second thin-film elements obtained as above a platinum film is formed as the upper electrode and the first thin-film element and the second thin-film element are obtained.

As described above, thin-film elements with different film thicknesses can be formed on the same substrate.

### Third Example

In the present example, a difference in a film thickness of a thin-film part according to a difference in a number of times repeating the precursor thin-film formation processing upon forming a thin-film part of a first thin-film element and a thin-film part of a second thin-film element will be examined.

Thin-film elements having thin-film parts with different film thicknesses are formed in the same way as in the second example other than that the numbers of application (number of times forming a precursor thin-film) upon forming the thin-film part of the first thin-film element and the thin-film part of the second thin-film element are changed as follows. Meanwhile, when the thin-film part of the first thin-film element and the thin-film part of the second thin-film element are formed, the high concentration ink of 0.5 mol/l which is prepared in the first example as a precursor solution is used for both of the thin-film elements.

For the first thin-film element a number of times of repetition of the processes in the flowchart shown in FIG. 11 is assumed to be one for the determination step S105 (m=1) and 8 for the determination step S107 (n=8) and the process is conducted.

For the second thin-film element a number of times of repetition of the processes in the flowchart shown in FIG. 11 is assumed to be two for the determination step S105 (m=2) and 8 for the determination step S107 (n=8) and the process is conducted.

That is, for the first thin-film element the thin-film part is formed by repeating eight times in total the flow of repeating the processing from the surface reforming processing (S101) to the heat decomposition processing (S104) once and of performing the crystallization processing (S106). For this reason the precursor thin-film formation processing (S102) is performed eight times in total.

Moreover, for the second thin-film element the thin-film part is formed by repeating eight times in total the flow of repeating the processing from the surface reforming processing (S101) to the heat decomposition processing (S104) twice and of performing the crystallization processing (S106). For this reason the precursor thin-film formation processing (S102) is performed 16 times in total.

As a result, the film thickness of the thin-film part of the first thin-film element is 0.7 μm, and the film thickness of the thin-film part of the second thin-film element is 1.3 μm.

Then, on the top sides of the first and second thin-film elements obtained as above, a platinum film is formed as the upper electrode and the first thin-film element and the second thin-film element are obtained.

As described above, thin-film elements with different film thicknesses can be formed on the same substrate.

### Fourth Example

In the present example, a difference in a film thickness of a thin-film part according to a difference in an application density upon forming a thin-film part of a first thin-film element and a thin-film part of a second thin-film element will be examined.

The thin-film parts are formed in the same way as in the first example other than that the high concentration ink of 0.5 mol/l which is prepared in the first example is used for any of the first thin-film element and the second thin-film element, and the application density is changed as follows and a number of times of repetition of the processes in the flowchart shown in FIG. 11 are changed.

The changes described as above will be explained in detail as follows.

First, a condition for the application density will be explained.

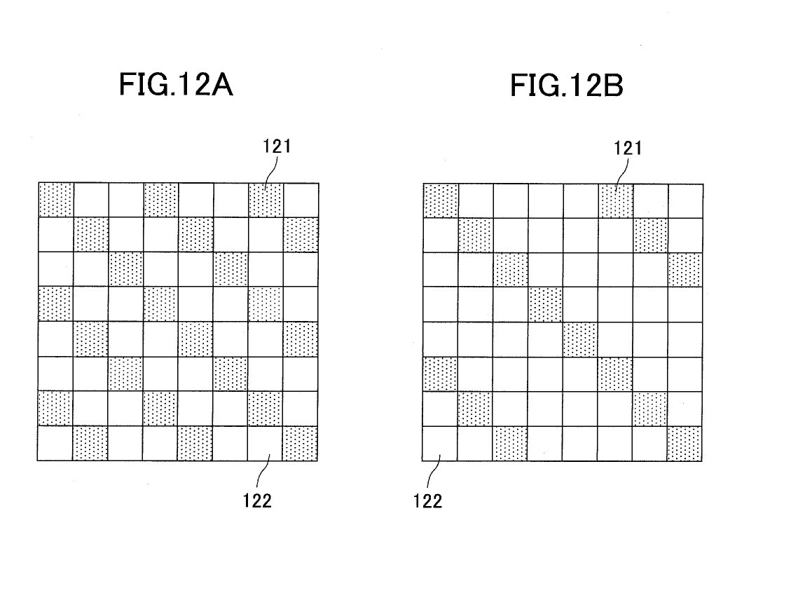

For the thin-film part of the first thin-film element liquid droplets of the precursor solution are supplied so as to be the thinning of ⅓. Specifically, as shown in FIG. 12A a bit pattern is formed so that a pixel 121 that receives liquid droplets of the precursor solution and a pixel 122 that does not receive liquid droplets of the precursor solution form a checkerboard pattern and a liquid drop pattern is supplied based on the bit pattern.

For the thin-film part of the second thin-film element liquid droplets of the precursor solution are supplied so as to be the thinning of ⅕. Specifically, as shown in FIG. 12B a bit pattern is formed so that the pixel 121 that receives liquid droplets of the precursor solution and the pixel 122 that does not receive liquid droplets of the precursor solution form a checkerboard pattern and a liquid drop pattern is supplied based on the bit pattern.

Next, the change in the number of times of repetition of the processes in the flowchart shown in FIG. 11 will be explained.

In the present example for both of the first and second thin-film elements a number of times of repetition of the processes in the flowchart shown in FIG. 11 are assumed to be one for the determination step S105 (m=1) and one for the determination step S107 (n=1) and the process is conducted. That is, the thin-film part is formed by performing once in total the flow of performing the crystallization processing (S106) after conducting once the processing from the surface reforming processing (S101) to the heat decomposition processing (S104).

As a result, the film thickness of the thin-film part of the first thin-film element is 80 nm, and the film thickness of the thin-film part of the second thin-film element is 50 nm.

Then, on the top sides of the first and second thin-film elements obtained as above a platinum film is formed as the upper electrode and the first thin-film element and the second thin-film element are obtained.

As described above, thin-film elements with different film thicknesses can be formed on the same substrate.

### Fifth Example

In the present example, thin-film elements having thin-film parts with different thicknesses are formed by changing the application density upon forming the thin-film part of the first thin-film element and the thin-film part of the second thin-film element.

The thin-film parts are formed in the same way as in the first example other than that the high concentration ink of 0.5 mol/l which is prepared in the first example is used for the first thin-film element and the second thin-film element, but the application density is changed as follows and a number of times of repetition of the processes in the flowchart shown in FIG. 11 are changed.

The changes described as above will be explained in detail as follows.

First, a condition for the application density will be explained.

For the thin-film part of the first thin-film element, liquid droplets of the precursor solution are supplied so as to be the thinning of ⅓. That is, as described above when a print pattern is divided by plural pixels, liquid droplets are supplied only to one row of pixels out of three rows of pixels.

For the thin-film part of the second thin-film element, liquid droplets of the precursor solution are supplied so as to be the thinning of ⅙. That is, as described above when a print pattern is divided by plural pixels, liquid droplets are supplied only to one row of pixels out of six rows of pixels.

Next, the change in the number of times of repetition of the processes in the flowchart shown in FIG. 11 will be explained.

In the present example for both of the first and second thin-film elements a number of times of repetition of the processes in the flowchart shown in FIG. 11 are assumed to be three for the determination step S105 (m=3) and eight for the determination step S107 (n=8) and the process is conducted. That is, the thin-film part is formed by performing eight times in total the flow of performing the crystallization processing (S106) after repeating three times the processing from the surface reforming processing (S101) to the heat decomposition processing (S104).

As a result, the film thickness of the thin-film part of the first thin-film element is 2000 nm, and the film thickness of the thin-film part of the second thin-film element is 1000 nm.

Then, on the top sides of the first and second thin-film elements obtained as above a platinum film is formed as the upper electrode and the first thin-film element and the second thin-film element are obtained.

As described above, thin-film elements with different film thicknesses can be formed on the same substrate.

Further, the present invention is not limited to these embodiments, but various variations and modifications may be made without departing from the scope of the present invention.

The present application is based on and claims the benefit of priority of Japanese Priority Application No. 2013-245292 filed on Nov. 27, 2013, the entire contents of which are hereby incorporated by reference.

1-8. (canceled)

9: A manufacturing method of an electronic device which includes a substrate, a first thin-film element formed on the substrate and having a lower electrode, a first upper electrode and a first thin-film part disposed between the lower electrode and the first upper electrode, and a second thin-film element formed on the substrate and having the lower electrode, a second upper electrode and a second thin-film part disposed between the lower electrode and the second upper electrode, a film thickness of the second thin-film part being different from a film thickness of the first thin-film part, the method comprising:
performing processing of forming a first precursor thin-film by applying a precursor solution using a printing method;
performing processing of forming a second precursor thin-film by applying the precursor solution using the printing method;
imparting energy to the first precursor thin-film to form the first thin-film part; and
imparting energy to the second precursor thin-film to form the second thin-film part.

10: The manufacturing method of the electronic device as claimed in claim 9, wherein
the first thin-film part is formed by repeatedly performing a plurality of times surface reforming processing, the processing of forming the first precursor thin-film, drying processing and heat decomposition processing and performing crystallization processing,
the second thin-film part is formed by repeatedly performing a plurality of times the surface reforming processing, the processing of forming the second precursor thin-film, the drying processing and the heat decomposition processing and performing the crystallization processing, and
a number of times of the processing of forming the first precursor thin-film is different from a number of times of the processing of forming the second precursor thin-film.

11: The manufacturing method of the electronic device as claimed in claim 9, wherein a concentration of the precursor solution used for forming the first precursor thin-film is different from a concentration of the precursor solution used for forming the second precursor thin-film.

12: The manufacturing method of the electronic device as claimed in claim 9, wherein the printing method is an ink jet method, and a density of application of the precursor solution upon forming the first precursor thin-film is different from a density of application of the precursor solution upon forming the second precursor thin-film.
